(19) United States
(12) Patent Application Publication
(10) Pub. No.: US 2026/0271648 A1
(43) Pub. Date: Sep. 10, 2026

(54) SEMICONDUCTOR DEVICE AND METHOD FOR MANUFACTURING THE SAME

(71) Applicant: Kioxia Corporation, Tokyo (JP)

(72) Inventor: Yukihiro YAMAMOTO, Yokkaichi (JP)

(73) Assignee: Kioxia Corporation, Tokyo (JP)

(21) Appl. No.: 19/325,743

(22) Filed: Sep. 11, 2025

(30) Foreign Application Priority Data
Mar. 10, 2025 (JP) 2025-037811

(51) Int. Cl. H01L 21/78; H01L 21/56; H01L 23/00; H01L 23/31

(52) U.S. Cl. CPC H10P 54/00; H10W 74/01; H10W 74/134; H10W 90/754

(57) ABSTRACT

A method includes forming, in a semiconductor substrate surface of a semiconductor substrate having a first pad, a first groove extending in a first direction and having a first side surface, a second side surface, and a first bottom surface; forming, over the first groove and the semiconductor substrate surface, a film containing metal; forming a first protrusion connected to a first portion of the film disposed on the first bottom surface by cutting the semiconductor substrate with a blade, the first protrusion extending upward from the first portion of the film and including the metal; placing the semiconductor substrate having the first protrusion on a first substrate surface of a first substrate having a second pad on the first substrate surface; and connecting the first pad to the second pad through a first wire, the first wire extending above and across the first protrusion.

### CROSS-REFERENCE TO RELATED APPLICATION(S)

This application is based upon and claims the benefit of priority from Japanese Patent Application No. 2025-037811, filed Mar. 10, 2025, the entire contents of which are incorporated herein by reference.

### FIELD

Embodiments described herein relate generally to a semiconductor device and a method for manufacturing the semiconductor device.

### BACKGROUND

A pad containing, for example, aluminum or the like is provided on the upper surface of a semiconductor package on which a semiconductor chip such as a NAND flash memory chip is stacked.

### DESCRIPTION OF THE DRAWINGS

FIG. 1 is a schematic top view of a semiconductor substrate of a first embodiment.

FIG. 2 is a schematic cross-sectional view illustrating a method for manufacturing a semiconductor device according to a first aspect of the first embodiment.

FIG. 3 is a schematic cross-sectional view illustrating the method for manufacturing the semiconductor device according to the first aspect of the first embodiment.

FIG. 4 is a schematic cross-sectional view illustrating the method for manufacturing the semiconductor device according to the first aspect of the first embodiment.

FIG. 5 is a schematic cross-sectional view illustrating the method for manufacturing the semiconductor device according to the first aspect of the first embodiment.

FIG. 6 is a schematic cross-sectional view illustrating a method for manufacturing a semiconductor device according to a second aspect of the first embodiment.

FIG. 7 is a schematic cross-sectional view illustrating the method for manufacturing the semiconductor device according to the second aspect of the first embodiment.

FIGS. 8A and 8B are schematic cross-sectional views illustrating the method for manufacturing the semiconductor device according to the second aspect of the first embodiment.

FIGS. 9A and 9B are schematic cross-sectional views illustrating a method for manufacturing a semiconductor device according to a third aspect of the first embodiment.

FIG. 10 is a schematic cross-sectional view illustrating a method for manufacturing a semiconductor device according to a fourth aspect of the first embodiment.

FIG. 11 is a schematic cross-sectional view illustrating a method for manufacturing a semiconductor device according to a fifth aspect of the first embodiment.

FIG. 12 is a schematic cross-sectional view illustrating a method for manufacturing a semiconductor device according to a comparative form of the first embodiment.

FIGS. 13A and 13B are schematic cross-sectional views illustrating the method for manufacturing the semiconductor device according to the comparative form of the first embodiment.

FIG. 14 is a schematic cross-sectional view illustrating a method for manufacturing a semiconductor device according to a second embodiment.

FIG. 15 is a schematic cross-sectional view illustrating the method for manufacturing the semiconductor device according to the second embodiment.

### DETAILED DESCRIPTION

Embodiments provide a semiconductor device with improved reliability and a method for manufacturing the semiconductor device.

The method for manufacturing the semiconductor device according to the embodiment includes forming, in a semiconductor substrate surface of a semiconductor substrate having a first pad, a first groove extending in a first direction parallel with the semiconductor substrate surface and having a first side surface, a second side surface facing the first side surface, and a first bottom surface. The method includes forming, over the first groove and the semiconductor substrate surface, a film containing metal, and a metal film is formed over the first groove as a second groove. The method includes forming a first protrusion connected to a first portion of the film disposed on the first bottom surface by cutting the semiconductor substrate with a blade such that the vertical line dropped from a side surface of the blade is positioned within the range of the first direction of the second groove, wherein the first protrusion extends upward from the first portion of the film and includes the metal. The method includes placing the semiconductor substrate having the first protrusion on a first substrate surface of a first substrate having a second pad on the first substrate surface. The method includes connecting the first pad to the second pad through a first wire, wherein the first wire extends above and across the first protrusion.

Hereinafter, the embodiments will be described with reference to the drawings. In the drawings, the same or similar parts are designated by the same or similar reference numerals.

In the present description, in order to indicate a positional relationship between components and the like, an upward direction in the drawings is described as “upper”, and a downward direction in the drawings is described as “lower”. In the present description, the concepts of “upper” and “lower” are not necessarily terms indicating a relation with the direction of gravity.

### First Embodiment

A method for manufacturing a semiconductor device according to the present embodiment includes forming, in a semiconductor substrate surface of a semiconductor substrate having a first pad, a first groove extending in a first direction parallel with the semiconductor substrate surface and having a first side surface, a second side surface facing the first side surface, and a first bottom surface, forming, over the first groove and the semiconductor substrate surface, a film containing metal, and a metal film is formed over the first groove as a second groove, forming a first protrusion connected to the film on the first bottom surface, protruding upward of the film on the first bottom surface, and containing the metal by cutting the semiconductor substrate by dicing with a blade such that the vertical line dropped from a first side surface of the blade is positioned within the range of the first direction of the second groove, placing the semiconductor substrate having the first protrusion on a first substrate surface of a first substrate having a second pad on the first substrate surface, and using a first wire, connecting the first pad and the second pad such that the first wire extends above and across the first protrusion.

The method for manufacturing the semiconductor device according to the present embodiment further includes forming, in the semiconductor substrate surface of the semiconductor substrate further having a third pad, a third groove extending in the first direction and having a third side surface, a fourth side surface facing the third side surface, and a second bottom surface, forming, over the first groove, the third groove, and the semiconductor substrate surface, the film containing the metal, and a metal film is formed over the third groove as a fourth groove, forming a second protrusion connected to the film on the second bottom surface, protruding upward of the film on the second bottom surface, and containing the metal by cutting the semiconductor substrate by the dicing with the blade such that the vertical line dropped from a second side surface of the blade is positioned within the range of the first direction of the fourth groove, placing the semiconductor substrate having the second protrusion on a second substrate surface of a second substrate having a fourth pad on the second substrate surface, and using a second wire, connecting the third pad and the fourth pad such that the second wire extends above and across the second protrusion.

A semiconductor device of the present embodiment includes a first substrate having a first substrate surface and a second pad provided on the first substrate surface, a semiconductor substrate provided on the first substrate and having a semiconductor substrate surface, a first pad provided on the semiconductor substrate surface, a step-like shape provided at an end of the semiconductor substrate surface and having a first bottom surface and a first side surface, a film provided on the semiconductor substrate surface and the step-like shape and containing metal, and a first protrusion connected to the film on the first bottom surface, protruding upward of the film, and containing the metal, and a first wire provided above the first protrusion and connected to the first pad and the second pad.

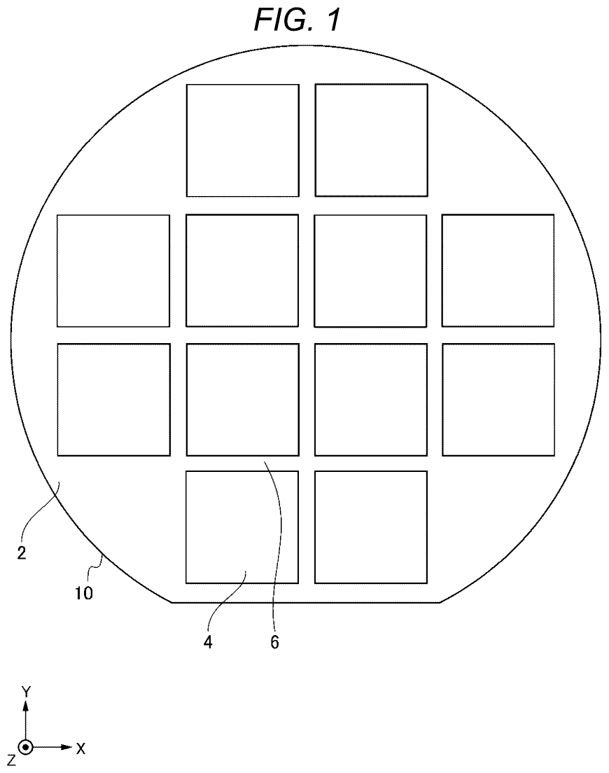

FIG. 1 is a schematic top view of a semiconductor substrate 10 of the first embodiment.

The semiconductor substrate 10 is, for example, a silicon (Si) substrate. The semiconductor substrate 10 may be a gallium nitride (GaN) substrate, a gallium arsenide (GaAs) substrate, a silicon carbide (SiC) substrate, or the like.

An element region 4 and a dicing line region 6 are provided in a semiconductor substrate surface 2 of the semiconductor substrate 10. In the element region 4, a semiconductor device such as a NAND flash memory chip is provided. The dicing line region 6 is a region to be cut by blade dicing, laser dicing, or other types of dicing. In the present embodiment, the semiconductor substrate 10 is cut by the blade dicing.

Here, an X direction, a Y direction perpendicularly intersecting the X direction, and a Z direction perpendicularly intersecting the X direction and the Y direction are defined. The semiconductor substrate surface 2 is provided parallel with the XY plane.

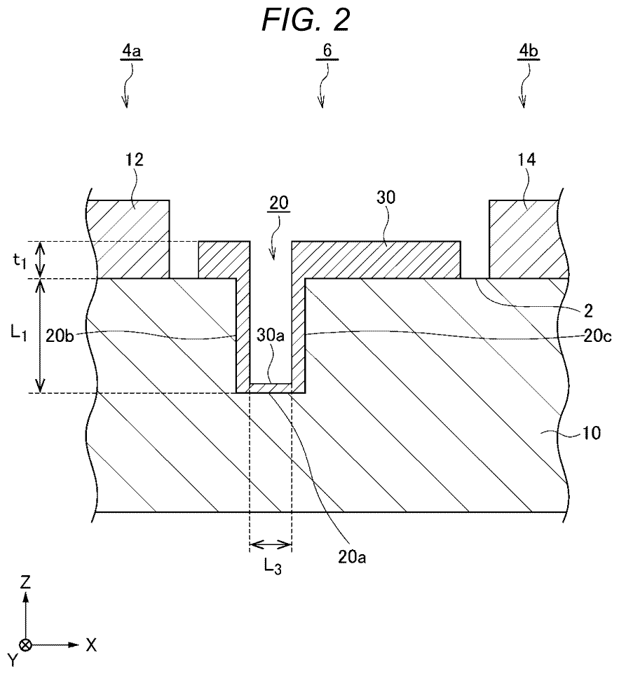

FIGS. 2 to 5 are schematic cross-sectional views illustrating a method for manufacturing a semiconductor device according to a first aspect of the present embodiment.

A pad 12 (one example of a first pad) is provided on an element region 4a. A pad 14 (one example of a third pad) is provided on an element region 4b. The pad 12 is connected, for example, to a semiconductor device, such as a NAND flash memory, provided on a semiconductor substrate 10 in the element region 4a. The pad 14 is connected, for example, to a semiconductor device, such as a NAND flash memory, provided on the semiconductor substrate 10 in the element region 4b. The pad 12 and the pad 14 contain, for example, gold (Au), copper (Cu), aluminum (Al), or the like (FIG. 2).

Here, in the semiconductor substrate surface 2, a first groove 20 extending in the Y direction (one example of a first direction) is formed, for example, by photolithography. The first groove 20 has a first side surface 20b, a second side surface 20c facing the first side surface 20b, and a first bottom surface 20a. (FIG. 2)

Next, a film 30 containing metal is formed over the first groove 20 and the semiconductor substrate surface 2, for example, by a chemical vapor deposition (CVD) method. Here, the metal is, for example, aluminum. In FIG. 2, the pad 12 and the pad 14 are provided apart from the film 30. However, the pad 12 or the pad 14 may be connected to the film 30 (FIG. 2).

A difference L₁ between the height of the first bottom surface 20a and the height of the semiconductor substrate surface 2 is preferably 5 μm or more.

A distance L₃ between the film 30 provided on the first side surface 20b and the film 30 provided on the second side surface 20c is preferably 5 μm or more.

In a case where the film thickness t₁ of the film 30 on the semiconductor substrate surface 2 is 700 nm or more, the method for manufacturing the semiconductor device according to the present embodiment is particularly preferably used.

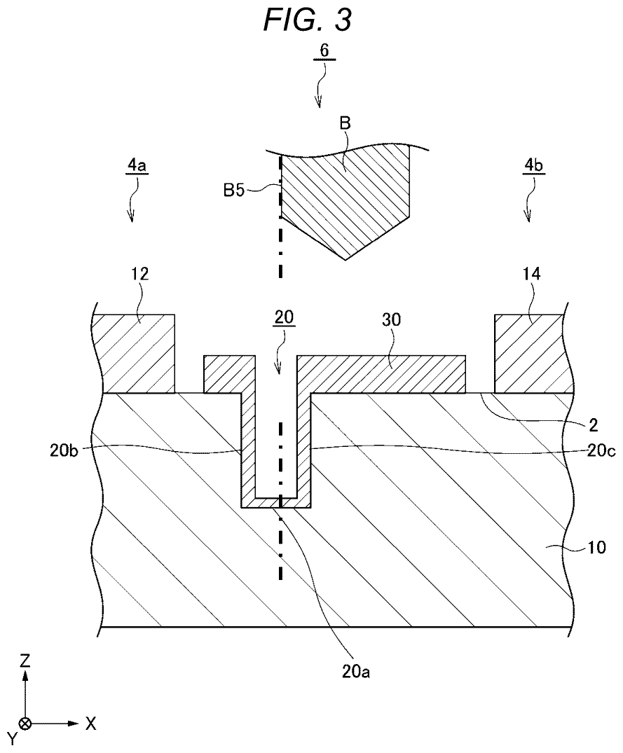

Next, When a metal film is formed over the first groove 20 as the second groove, the semiconductor substrate 10 is cut by blade dicing with a blade B such that the vertical line dropped from a first side surface B5 of the blade B is positioned within the range of the first direction of the second groove (FIG. 3).

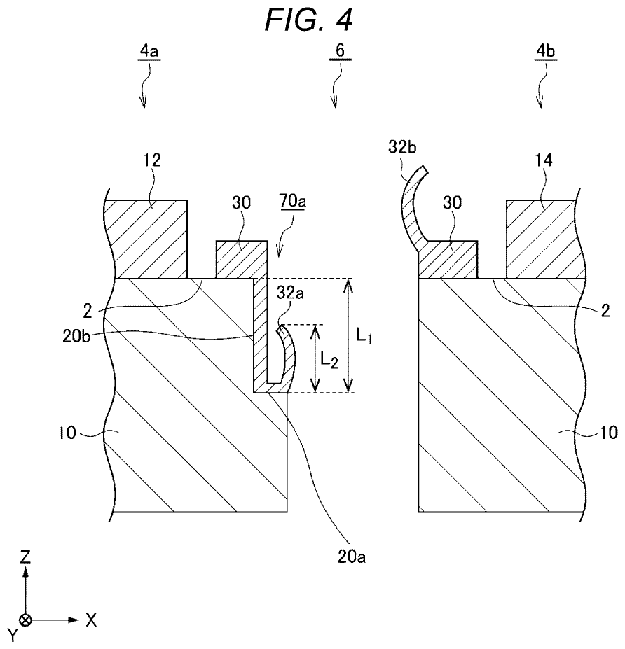

By such blade dicing, a step-like shape 70a is formed at an end of the semiconductor substrate 10. The step-like shape 70a has the first bottom surface 20a of the first groove 20, the first side surface 20b of the first groove 20, and the semiconductor substrate surface 2 (FIG. 4).

Moreover, by the blade dicing, a protrusion (one example of a first protrusion) 32a is formed. The protrusion 32a is connected to the film 30 on the first bottom surface 20a. Moreover, the protrusion 32a protrudes upward of the film 30 on the first bottom surface 20a. The protrusion 32a contains the metal contained in the film 30 (FIG. 4).

The height L₂ of the protrusion 32a is preferably less than 5 μm. The height L₂ of the protrusion 32a is measured from the first bottom surface 20a.

Moreover, by the blade dicing, a protrusion 32b is formed. The protrusion 32b is connected to the film 30 on the semiconductor substrate surface 2. Moreover, the protrusion 32b protrudes upward of the film 30 on the semiconductor substrate surface 2. The protrusion 32b contains the metal contained in the film 30.

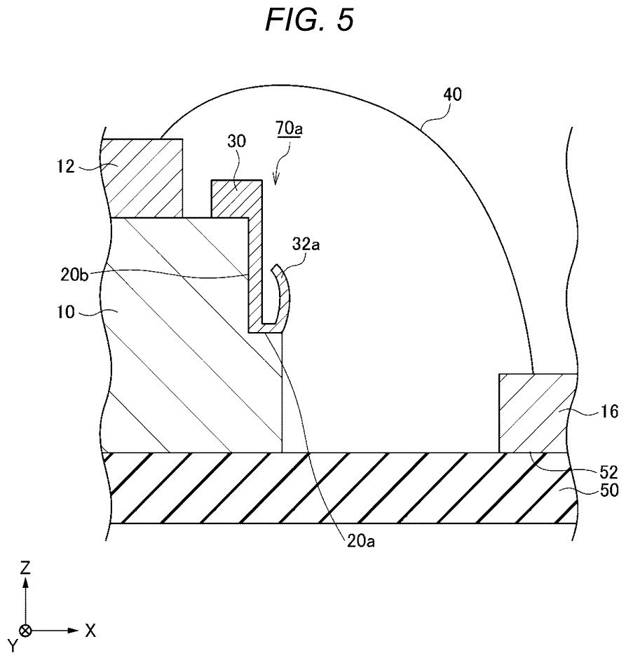

A pad 16 (one example of a second pad) is provided on a first substrate surface 52 of a first substrate 50. Here, the semiconductor substrate 10 having the protrusion 32a is placed on the first substrate surface 52 adjacent to the pad 16 (FIG. 5).

The first substrate 50 is an insulating substrate containing, for example, a resin material. However, the first substrate 50 may be a semiconductor substrate such as a silicon (Si) substrate, a gallium nitride (GaN) substrate, a gallium arsenide (GaAs) substrate, or a silicon carbide (SiC) substrate.

Next, using a wire 40 (one example of a first wire), the pad 12 and the pad 16 are connected such that the wire 40 extends above and across the protrusion 32a (FIG. 5).

The wire 40 is, for example, a bonding wire. The wire 40 contains, for example, gold (Au), silver (Ag), copper (Cu), or the like. The wire 40 is connected to the pad 12 and the pad 16, for example, by bonding.

A portion of the semiconductor substrate 10 including the element region 4b is not used for manufacturing the semiconductor device.

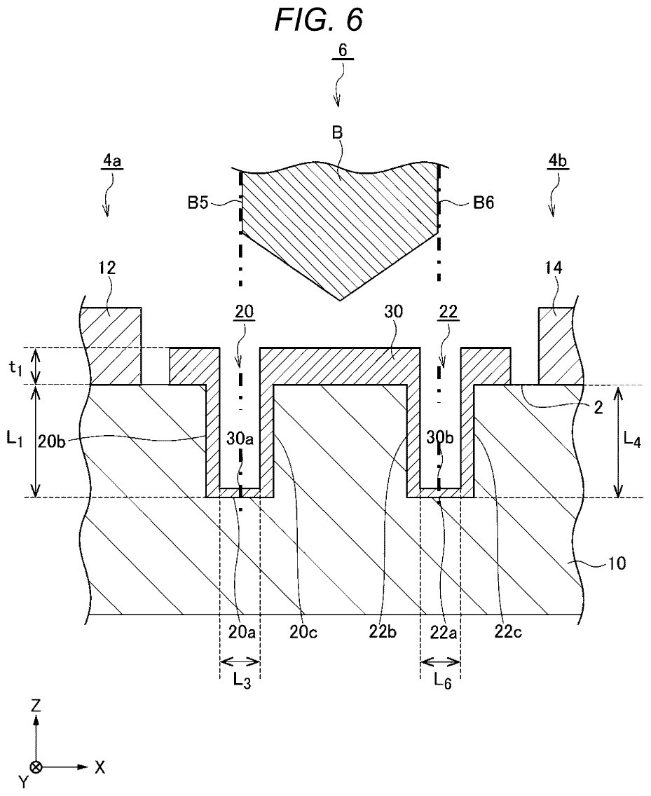

FIGS. 6 to 8(b) are schematic cross-sectional views illustrating a method for manufacturing a semiconductor device according to a second aspect of the present embodiment.

In the semiconductor substrate surface 2, the first groove 20 and a third groove 22 extending in the Y direction are formed, for example, by photolithography (FIG. 6). The third groove 22 has a third side surface 22b, a fourth side surface 22c facing the third side surface 22b, and a second bottom surface 22a.

Next, the film 30 containing the metal is formed over the first groove 20, the third groove 22, and the semiconductor substrate surface 2 (FIG. 6). In FIG. 6, the pad 12 and the pad 14 are provided apart from the film 30. However, the pad 12 or the pad 14 may be connected to the film 30. For example, the first groove 20 and the third groove 22 are provided between the pad 12 and the pad 14.

A difference L₄ between the height of the second bottom surface 22a and the height of the semiconductor substrate surface 2 is preferably 5 μm or more.

A distance L₆ between the film 30 provided on the third side surface 22b of the second groove 22 and the film 30 provided on the fourth side surface 22c is preferably 5 μm or more.

Next, the metal film is formed over the third groove 22 as a fourth groove,, the semiconductor substrate 10 is cut by the blade dicing with the blade B such that the vertical line dropped from a second side surface B6 of the blade B is positioned within the range of the first direction of the fourth groove (FIG. 6). (FIG. 6).

By the blade dicing, the step-like shape 70a is formed at the end of the semiconductor substrate 10 having the pad 12. The step-like shape 70a has the first bottom surface 20a of the first groove 20, the first side surface 20b of the first groove 20, and the semiconductor substrate surface 2.

Moreover, by the blade dicing, a step-like shape 70b is formed at an end of the semiconductor substrate 10 having the pad 14. The step-like shape 70b has the second bottom surface 22a of the second groove 22, the fourth side surface 22c of the second groove 22, and the semiconductor substrate surface 2.

Moreover, by the blade dicing, the protrusion 32a is formed. The protrusion 32a is connected to the film 30 on the first bottom surface 20a. The protrusion 32a protrudes upward of the film 30 on the first bottom surface 20a. The protrusion 32a contains the metal contained in the film 30 (FIG. 7).

Moreover, by the blade dicing, a protrusion 32d (one example of a second protrusion) is formed. The protrusion 32d is connected to the film 30 on the second bottom surface 22a. The protrusion 32d protrudes upward of the film 30 on the second bottom surface 22a of the second groove 22. The protrusion 32d contains the metal contained in the film 30 (FIG. 7).

The height L₅ of the protrusion 32d is preferably less than 5 μm. The height L₅ of the protrusion 32d is measured from the second bottom surface 22a.

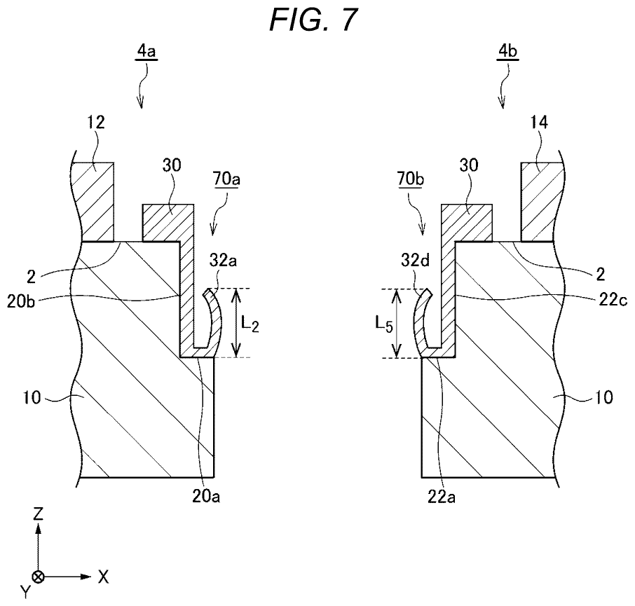

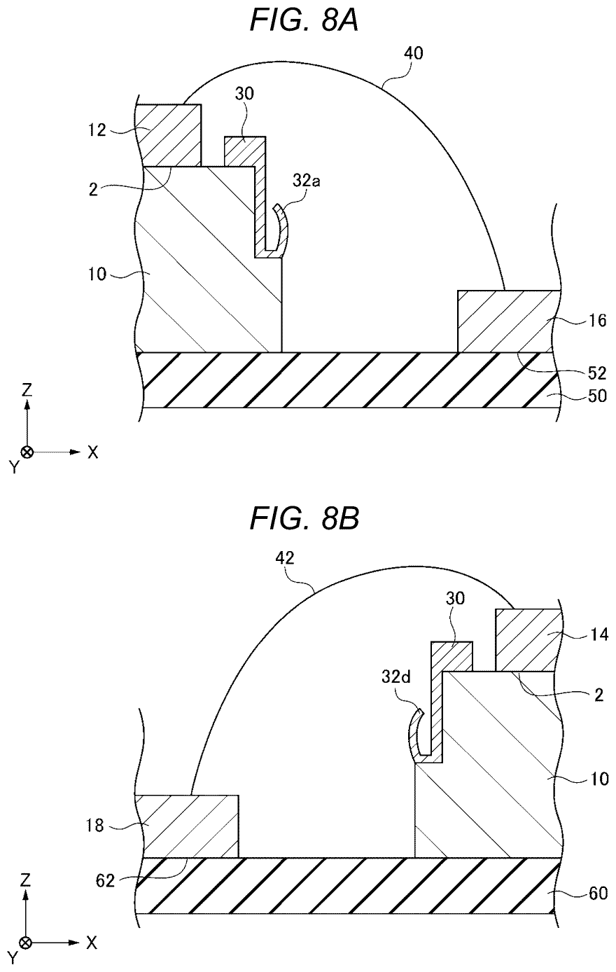

The pad 16 is provided on the first substrate surface 52 of the first substrate 50. Here, the semiconductor substrate 10 having the protrusion 32a is placed on the first substrate surface 52 adjacent to the pad 16 (FIG. 8A).

A pad 18 (one example of a fourth pad) is provided on a second substrate surface 62 of a second substrate 60. Here, the semiconductor substrate 10 having the protrusion 32d is placed on the second substrate surface 62 adjacent to the pad 18 (FIG. 8B).

The second substrate 60 is an insulating substrate containing, for example, a resin material. However, the second substrate 60 may be a semiconductor substrate such as a silicon (Si) substrate, a gallium nitride (GaN) substrate, a gallium arsenide (GaAs) substrate, or a silicon carbide (SiC) substrate.

Next, using the wire 40, the pad 12 and the pad 16 are connected such that the wire 40 extends above and across the protrusion 32a (FIG. 8A).

Moreover, using a wire 42 (one example of a second wire), the pad 14 and the pad 18 are connected such that the wire 42 extends above and across the protrusion 32d (FIG. 8B).

The wire 42 is, for example, a bonding wire. The wire 42 contains, for example, gold (Au), silver (Ag), copper (Cu), or the like. The wire 42 is connected to the pad 14 and the pad 18, for example, by bonding.

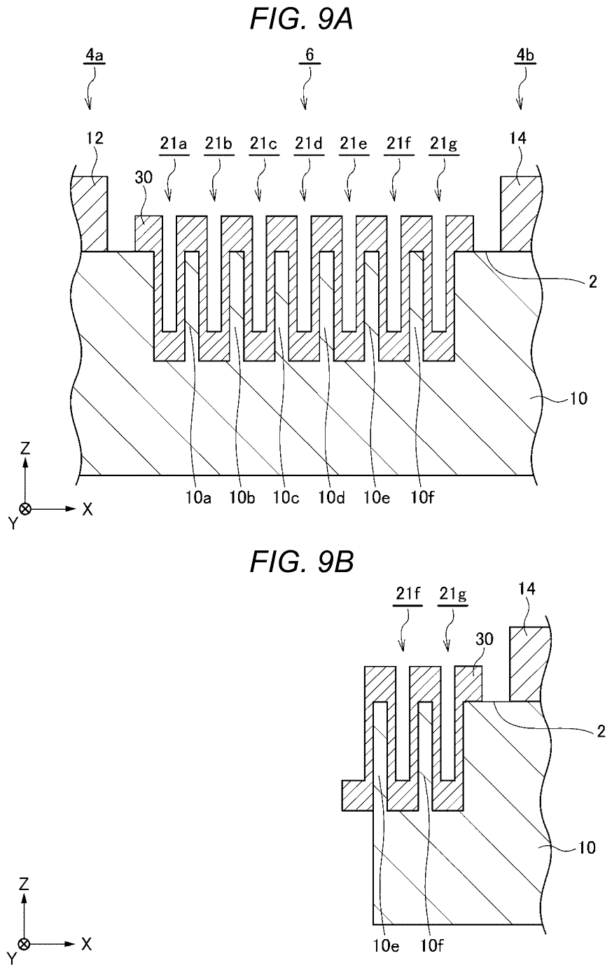

FIGS. 9A and 9B are schematic cross-sectional views illustrating a method for manufacturing a semiconductor device according to a third aspect of the present embodiment.

In the dicing line region 6 of the semiconductor substrate surface 2 of the semiconductor substrate 10, seven grooves which are a groove 21a, a groove 21b, a groove 21c, a groove 21d, a groove 21e, a groove 21f, and a groove 21g are provided. Part 10a of the semiconductor substrate 10 is provided between the groove 21a and the groove 21b. Part 10b of the semiconductor substrate 10 is provided between the groove 21b and the groove 21c. Part 10c of the semiconductor substrate 10 is provided between the groove 21c and the groove 21d. Part 10d of the semiconductor substrate 10 is provided between the groove 21d and the groove 21e. Part 10e of the semiconductor substrate 10 is provided between the groove 21e and the groove 21f. Part 10f of the semiconductor substrate 10 is provided between the groove 21f and the groove 21g. The number of grooves 21 is not limited to seven (FIG. 9A).

After the dicing with the blade (not illustrated), for example, the semiconductor substrate 10 having the pad 14 has the part 10e of the semiconductor substrate 10 and the part 10f of the semiconductor substrate 10. As the number of grooves 21 increases, the length of part of the semiconductor substrate 10 in the X direction decreases. Thus, the part of the semiconductor substrate 10 is easily broken away.

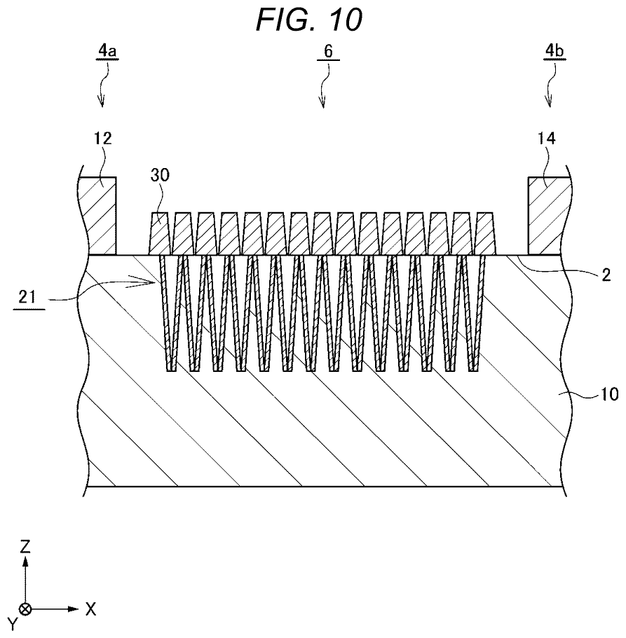

FIG. 10 is a schematic cross-sectional view illustrating a method for manufacturing a semiconductor device according to a fourth aspect of the present embodiment. As the number of grooves 21 increases, a portion of the film 30 formed on the semiconductor substrate surface 2 increases in size. This is because upon formation of the film 30, it is difficult to form the film 30 inside the groove 21. In this case, it is considered that after the dicing with the blade, a portion of the semiconductor substrate 10 provided between the groove 21 and the groove 21 is more easily broken away.

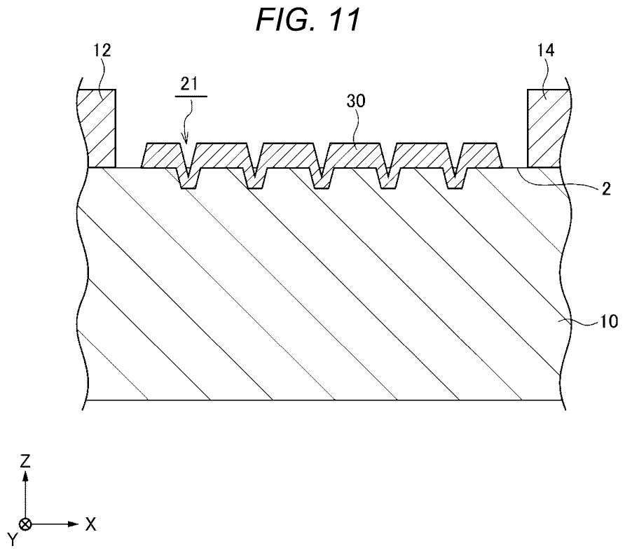

FIG. 11 is a schematic cross-sectional view illustrating a method for manufacturing a semiconductor device according to a fifth aspect of the present embodiment. It is considered that due to an increase in the number of grooves 21, after the dicing with the blade, a portion of the semiconductor substrate 10 provided between the groove 21 and the groove 21 is more easily broken away.

Next, operations and effects of the method for manufacturing the semiconductor device and the semiconductor device according to the present embodiment are described.

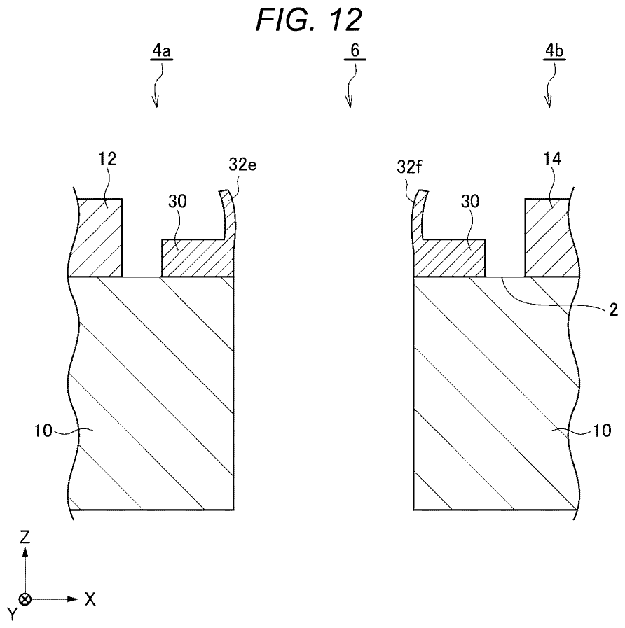

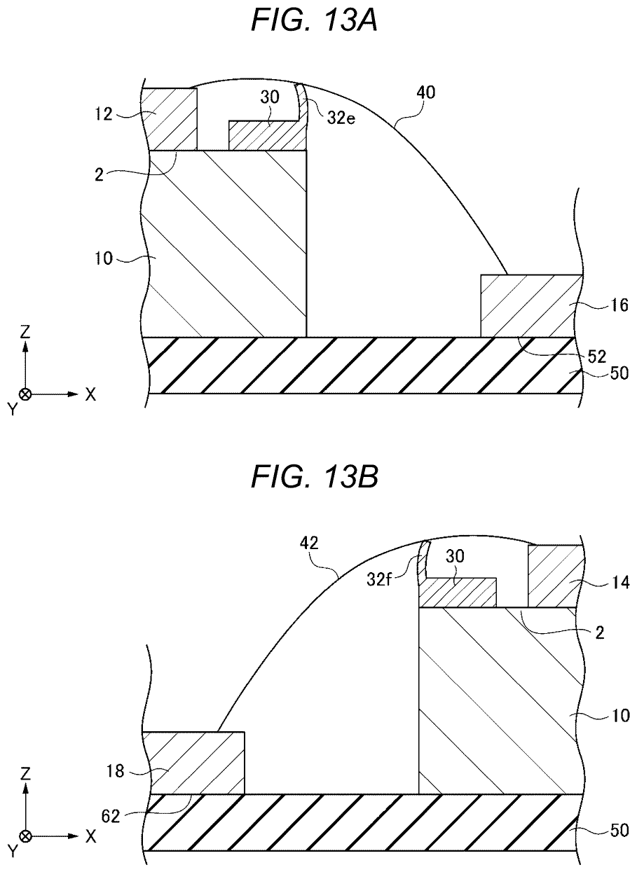

FIGS. 12, 13A, and 13B are schematic cross-sectional views illustrating a method for manufacturing a semiconductor device according to a comparative form of the present embodiment. In the method for manufacturing the semiconductor device according to the comparative form, no first groove 20 and second groove 22 are provided. Here, when the blade dicing is performed, a protrusion 32e and a protrusion 32f protruding upward of the film 30 on the semiconductor substrate surface 2 are formed (FIG. 12). In this case, when the connection is made through the wire 40, the protrusion 32e and the wire 40 may contact each other because the protrusion 32e is provided higher than the semiconductor substrate surface 2. Moreover, the wire 40 may be disconnected by the protrusion 32e (FIG. 13A). In this case, when the connection is made through the wire 42, the protrusion 32f and the wire 42 may contact each other because the protrusion 32f is provided higher than the semiconductor substrate surface 2. Moreover, the wire 42 may be disconnected by the protrusion 32f (FIG. 13B).

Thus, the method for manufacturing the semiconductor device according to the present embodiment includes forming, in a semiconductor substrate surface of a semiconductor substrate having a first pad, a first groove extending in a first direction parallel with the semiconductor substrate surface and having a first side surface, a second side surface facing the first side surface, and a first bottom surface, forming, over the first groove and the semiconductor substrate surface, a film containing metal, a metal film is formed over the first groove as a second groove, forming a first protrusion connected to the film on the first bottom surface, protruding upward of the film on the first bottom surface, and containing the metal by cutting the semiconductor substrate by dicing with a blade such that the vertical line dropped from a first side surface of the blade is positioned within the range of the first direction of the second groove, placing the semiconductor substrate having the first protrusion on a first substrate surface of a first substrate having a second pad on the first substrate surface, and using a first wire, connecting the first pad and the second pad such that the first wire extends above and across the first protrusion.

In the method for manufacturing the semiconductor device according to the present embodiment, the first groove 20 and a second groove which the first groove is covered by a metal film is formed in the semiconductor substrate surface 2. Moreover, the blade dicing is performed with the blade such that the vertical line dropped from a first side surface B5 of the blade B is positioned within the range of the first direction of the second groove 20. Thus, the protrusion 32a is formed to be connected to the film on the first bottom surface 20a. Consequently, the formation position of the protrusion 32a is a lower position. As a result, the disconnection of the wire 40 by the protrusion 32a is less likely to occur. Consequently, the semiconductor device with improved reliability and the method for manufacturing the semiconductor device can be provided.

The difference between the height of the first bottom surface 20a and the height of the semiconductor substrate surface 2 is preferably 5 μm or more. This is because the protrusion 32a is formed sufficiently lower than the semiconductor substrate surface 2, and therefore, the disconnection of the wire 40 by the protrusion 32a is less likely to occur.

Similarly, the difference between the height of the second bottom surface 22a and the height of the semiconductor substrate surface 2 is preferably 5 μm or more.

The distance between the film 30 provided on the first side surface 20b and the film 30 provided on the second side surface 20c is preferably 5 μm or more. The blade B may be misaligned. However, as long as the distance between the film 30 provided on the first side surface 20b and the film 30 provided on the second side surface 20c is 5 μm or more, the first side surface B5 of the blade B can be easily disposed above the first groove 20 even in consideration of such misalignment.

Similarly, the distance L₆ between the film 30 provided on the third side surface 22b and the film 30 provided on the fourth side surface 22c is preferably 5 μm or more.

The height L₂ of the protrusion 32a and the height L₅ of the protrusion 32d are preferably less than 5 μm. This is for reliably avoiding the contact between the wire and the protrusion.

As the film thickness of the film 30 on the semiconductor substrate surface 2 increases, the film thickness of the film 30 on the first bottom surface 20a of the first groove 20 and the film thickness of the film 30 on the second bottom surface 22a of the second groove 22 also increase. In this case, the protrusion 32a and the protrusion 32d are easily formed. In a case where the film thickness t₁ of the film 30 on the semiconductor substrate surface 2 is 700 nm or more, the protrusion 32a and the protrusion 32d are particularly easily formed, and therefore, the method for manufacturing the semiconductor device according to the present embodiment is particularly preferably used.

According to the semiconductor device and the method for manufacturing the semiconductor device according to the present embodiment, the semiconductor device with the improved reliability and the method for manufacturing the semiconductor device can be provided.

### Second Embodiment

A method for manufacturing a semiconductor device according to the present embodiment includes forming, in a semiconductor substrate surface of a semiconductor substrate having a first pad, a first groove extending in a first direction parallel with the semiconductor substrate surface and having a first side surface, a second side surface facing the first side surface, and a first bottom surface, forming, over the first groove and the semiconductor substrate surface, a film containing metal, forming a third protrusion connected to the film on the first bottom surface, protruding upward of the film, and containing the metal by cutting the first groove by first dicing with first laser light, cutting the semiconductor substrate surface by second dicing with second laser light, placing the semiconductor substrate having the first protrusion on a substrate surface of a substrate having a second pad on the substrate surface, and using a first wire, connecting the first pad and the second pad such that the first wire extends above and across the third protrusion.

The method for manufacturing the semiconductor device according to the present embodiment further includes forming, in the semiconductor substrate surface of the semiconductor substrate further having a third pad, a second groove extending in the first direction and having a third side surface, a fourth side surface facing the third side surface, and a second bottom surface, forming, over the first groove, the second groove, and the semiconductor substrate surface, the film containing the metal, forming a fourth protrusion connected to the film on the second bottom surface, protruding upward of the film on the second bottom surface, and containing the metal by cutting the second groove by third dicing with third laser light, placing the semiconductor substrate having the fourth protrusion on a second substrate surface of a second substrate having a fourth pad on the second substrate surface, and using a second wire, connecting the third pad and the fourth pad such that the second wire extends above and across the fourth protrusion.

A semiconductor device of the present embodiment includes a first substrate having a first substrate surface and a second pad provided on the first substrate surface, a semiconductor substrate provided on the first substrate and having a semiconductor substrate surface, a first pad provided on the semiconductor substrate surface, a step-like shape provided at an end of the semiconductor substrate surface and having a first bottom surface and a first side surface, a film provided on the semiconductor substrate surface and the step-like shape and containing metal, and a third protrusion connected to the film on the first bottom surface, protruding upward of the film, and containing the metal, and a first wire provided above the third protrusion and connected to the first pad and the second pad.

Here, description of contents overlapping with those of the first embodiment is omitted.

In the present embodiment, dicing with laser light is performed.

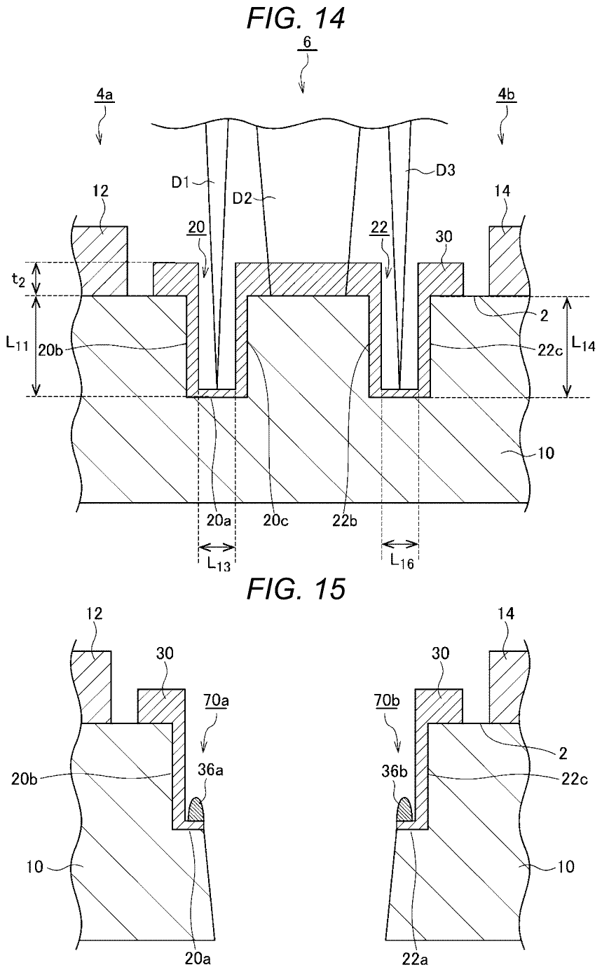

FIGS. 14 and 15 are schematic cross-sectional views illustrating the method for manufacturing the semiconductor device according to the present embodiment.

In the present embodiment, the first groove 20 is cut by dicing with first laser light D1. Moreover, the second groove 22 is cut by dicing with third laser light D3. Moreover, the semiconductor substrate 10 between the first groove 20 and the second groove 22 is cut by dicing with second laser light D2 (FIG. 14).

By the dicing with the second laser light D2, the semiconductor substrate 10 and the film 30 between the first groove 20 and the second groove 22 are eliminated (FIG. 15).

By the dicing with the first laser light D1, a third protrusion 36a connected to the film 30 on the first bottom surface 20a, protruding upward of the film 30, and containing the metal is formed.

By the dicing with the third laser light D3, a fourth protrusion 36b connected to the film 30 on the second bottom surface 22a, protruding upward of the film 30, and containing the metal is formed.

Subsequent manufacturing steps are similar to those of the first embodiment.

The spot diameter of the second laser light D2 is preferably greater than the spot diameter of the first laser light D1 and the spot diameter of the third laser light D3. This is because the semiconductor substrate 10 and the film 30 between the first groove 20 and the second groove 22 can be quickly eliminated.

According to the semiconductor device and the method for manufacturing the semiconductor device according to the present embodiment, the semiconductor device with the improved reliability and the method for manufacturing the semiconductor device can also be provided.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, comprising:
forming, in a semiconductor substrate surface of a semiconductor substrate having a first pad, a first groove extending in a first direction parallel with the semiconductor substrate surface and having a first side surface, a second side surface facing the first side surface, and a first bottom surface;
forming, over the first groove and the semiconductor substrate surface, a film containing metal, when a metal film is formed over the first groove as a second groove,
forming a first protrusion connected to a first portion of the film disposed on the first bottom surface by cutting the semiconductor substrate with a blade such that the vertical line dropped from a first side surface of the blade is positioned within the range of the first direction of the second groove, wherein the first protrusion extends upward from the first portion of the film and includes the metal;
placing the semiconductor substrate having the first protrusion on a first substrate surface of a first substrate having a second pad on the first substrate surface; and
connecting the first pad to the second pad through a first wire, wherein the first wire extends above and across the first protrusion.

2. The method for manufacturing the semiconductor device according to claim 1, wherein a difference between a height of the first bottom surface and a height of the semiconductor substrate surface is equal to or greater than 5 micrometers (μm).

3. The method for manufacturing the semiconductor device according to claim 1, wherein a distance between a second portion of the film provided on the first side surface and a third portion of the film provided on the second side surface is equal to or greater than 5 (μm).

4. The method for manufacturing the semiconductor device according to claim 1, wherein a height of the first protrusion is less than 5 (μm).

5. The method for manufacturing the semiconductor device according to claim 1, wherein a film thickness of the film on the semiconductor substrate surface is equal to or greater than 700 nanometers (nm).

6. The method for manufacturing the semiconductor device according to claim 1, further comprising:
forming, in the semiconductor substrate surface of the semiconductor substrate further having a third pad, a third groove extending in the first direction and having a third side surface, a fourth side surface facing the third side surface, and a second bottom surface;
forming, over the first groove, the second groove, and the semiconductor substrate surface, the film containing the metal, when a metal film is formed over the third groove as a fourth groove,
forming a second protrusion connected to a fourth portion of the film on the second bottom surface by dicing the semiconductor substrate with the blade having a blade such that the vertical line dropped from a first side surface of the blade is positioned within the range of the first direction of the fourth groove, wherein the second protrusion extends upward from the fourth portion of the film and contains the metal;
placing the semiconductor substrate having the second protrusion on a second substrate surface of a second substrate having a fourth pad on the second substrate surface; and
connecting the third pad to the fourth pad through a second wire, wherein the second wire extends above and across the second protrusion.

7. A semiconductor device comprising:
a first substrate including:
a first substrate surface; and
a second pad provided on the first substrate surface;
a semiconductor substrate provided on the first substrate, and having a semiconductor substrate surface;
a first pad provided on the semiconductor substrate surface;
a step-like shape provided at an end of the semiconductor substrate surface and having a first bottom surface and a first side surface;
a film provided on the semiconductor substrate surface and the step-like shape and containing metal; and
a first protrusion connected to a first portion of the film on the first bottom surface, extending upward from the first portion of the film, and containing the metal; and
a first wire provided above the first protrusion and connected to the first pad and the second pad.

8. The semiconductor device according to claim 7, wherein a difference between a height of an upper surface of the film on the first bottom surface and a height of the semiconductor substrate surface is equal to or greater than 5 (μm).

9. The semiconductor device according to claim 7, wherein a height of the first protrusion is less than 5 μm.

10. The semiconductor device according to claim 7, wherein a film thickness of the film is equal to or greater than 700 nm.

11. A method for manufacturing a semiconductor device, comprising:
forming, in a semiconductor substrate surface of a semiconductor substrate having a first pad, a first groove extending in a first direction parallel with the semiconductor substrate surface and having a first side surface, a second side surface facing the first side surface, and a first bottom surface;
forming, over the first groove and the semiconductor substrate surface, a film containing metal;
forming a third protrusion connected to a first portion of the film on the first bottom surface by cutting the first groove with first laser light, wherein the third protrusion extends upward from the first portion of the film, and contains the metal;
cutting the semiconductor substrate surface with second laser light;
placing the semiconductor substrate having the third protrusion on a substrate surface of a substrate having a second pad on the substrate surface; and
connecting the first pad to the second pad through a first wire, wherein the first wire extends above and across the third protrusion.

12. The method for manufacturing the semiconductor device according to claim 11, wherein the first laser light and the second laser light are simultaneously applied.

13. The method for manufacturing the semiconductor device according to claim 11, wherein a spot diameter of the second laser light is greater than a spot diameter of the first laser light.

14. The method for manufacturing the semiconductor device according to claim 11, further comprising:
forming, in the semiconductor substrate surface of the semiconductor substrate further having a third pad, a second groove extending in the first direction and having a third side surface, a fourth side surface facing the third side surface, and a second bottom surface;
forming, over the first groove, the second groove, and the semiconductor substrate surface, the film containing the metal;
forming a fourth protrusion connected to a second portion of the film on the second bottom surface by cutting the second groove with third laser light, wherein the fourth protrusion extends upward from the second portion of the film and contains the metal;
placing the semiconductor substrate having the fourth protrusion on a second substrate surface of a second substrate having a fourth pad on the second substrate surface; and
connecting the third pad to the fourth pad through a second wire, wherein the second wire extends above and across the fourth protrusion.

15. The method for manufacturing the semiconductor device according to claim 14, wherein a spot diameter of the second laser light is greater than a spot diameter of the third laser light.

16. A semiconductor device comprising:
a first substrate having:
a first substrate surface; and
a second pad provided on the first substrate surface;
a semiconductor substrate provided on the first substrate and having a semiconductor substrate surface;
a first pad provided on the semiconductor substrate surface;
a step-like shape provided at an end of the semiconductor substrate surface and having a first bottom surface and a first side surface;
a film provided on the semiconductor substrate surface and the step-like shape and containing metal; and
a third protrusion connected to a portion of the film on the first bottom surface, extending upward from the portion of the film, and containing the metal; and
a first wire provided above the third protrusion and connected to the first pad and the second pad.
